(19) United States
(12) Patent Application Publication
(10) Pub. No.: US 2016/0343924 A1
(43) Pub. Date: Nov. 24, 2016

(54) LED-Based Light Emitting Devices Having Metal Spacer Layers

(71) Applicant: Cree, Inc., Durham, NC (US)

(72) Inventors: Bradley Earl Williams, Cary, NC (US); Christopher Brooks Henderson, Raleigh, NC (US)

(21) Appl. No.: 14/718,316

(22) Filed: May 21, 2015

(51) Int. Cl. H01L 33/62; H01L 33/60; H01L 33/48

(52) U.S. Cl. CPC H01L 33/62; H01L 33/486; H01L 33/60

(57) ABSTRACT

Light emitting devices include an LED that includes an n-type semiconductor layer and a p-type semiconductor layer that is stacked on top of the n-type semiconductor layer. A p-contact metallization stack is on top of the p-type semiconductor layer. An opening extends through the p-type semiconductor layer and the p-contact metallization stack that has a first region that penetrates the p-type semiconductor layer to expose the n-type semiconductor layer and a second region that penetrates the p-contact metallization stack. A bond metal stack is on top of the p-contact metallization stack, and a metal spacer layer is provided between the bond metal stack and the stacked semiconductor layers. The metal spacer layer fills the first region and at least partly fills the second region of the opening so that a lower surface of the bond metal stack is above a top surface of the p-type semiconductor layer.

### FIELD

The present invention relates generally to light emitting diode (“LED”)-based light emitting devices and, more particularly, to LED-based light emitting devices that are bonded to carrier substrates or other mounting surfaces.

### BACKGROUND

LEDs are solid state lighting devices that convert electric energy into light. LEDs include both semiconductor-based LEDs and organic LEDs. Semiconductor-based LEDs typically include a plurality of semiconductor layers that are epitaxially grown on a semiconductor or non-semiconductor growth substrate such as, for example, sapphire, silicon, silicon carbide, gallium nitride or gallium arsenide substrates. One or more semiconductor p-n junctions are formed in these epitaxial layers. When a sufficient voltage is applied across the p-n junction, electrons in the n-type semiconductor layers and holes in the p-type semiconductor layers flow in opposite directions. When an electron and a hole collide they recombine and a photon of light is emitted, which is how LEDs generate light. The epitaxial structure may include cladding layers, quantum wells or other structures that are designed to trap some of the electrons and holes in order to increase the rate at which the electrons and holes recombine. The wavelength distribution of the light emitted by an LED generally depends on the semiconductor materials used to form the LED and the structure of the thin epitaxial layers. The substrate may be partially or fully removed after the epitaxial layers are formed to reduce the thickness of the device and/or to improve light extraction from the device.

Many LEDs that are manufactured today are formed using gallium nitride (GaN)-based semiconductor materials. These LEDs typically include a plurality of gallium nitride-based semiconductor layers such as gallium nitride layers, aluminum gallium nitride layers, indium gallium nitride layers, aluminum indium gallium nitride layers and the like. Gallium nitride-based LEDs typically include an insulating or semiconducting growth substrate such as silicon carbide or sapphire. The gallium nitride-based epitaxial layers are formed on this growth substrate using epitaxial growth techniques. An anode contact may ohmically contact a p-type semiconductor layer of the device (typically, an exposed p-type epitaxial layer) and a cathode contact may ohmically contact an n-type semiconductor layer of the device (such as the substrate or an exposed n-type epitaxial layer) so that an operating voltage may be applied across the device. Wire bonds and/or surface contact structures are typically used to connect the anode and cathode contacts to the voltage source. The anode and/or cathode contacts may be multi-layer structures and may include layers that perform various functions such as, for example, ohmic contact layers, reflector layers, barrier layers and/or bond metal layers.

LEDs are typically fabricated in a “wafer” level process in which the semiconductor layers are grown on a growth substrate in the form of a wafer, the metallization and patterning processes are performed, and then the resulting structure is diced into hundreds or thousands of LED chips. The singulated LED chips may be mounted on structures and electrically connected to voltage sources to provide operational light emitting devices.

LED chips are routinely mounted with the growth substrate side of the chip attached to a submount such as a lead frame, a printed circuit board or other mounting structure. In this mounting arrangement, the light from the LED is primarily extracted through the top surface of the LED that is opposite the growth substrate and perhaps through sidewalls of the LED structure. LED chips are also routinely mounted in a so-called “flip-chip” orientation in which the LED chip is mounted to the submount with the growth substrate facing up (i.e. away from the submount). With flip-chip mounted LEDs, the light is primarily extracted through the growth substrate and the sidewalls of the LED structure. In some flip-chip LED designs, the growth substrate may be thinned or removed completely, typically during a wafer level process (i.e., prior to dicing), to expose an underlying semiconductor layer and the light may be emitted through the exposed semiconductor layer. In some flip-chip LED designs, a so-called “carrier substrate” may be bonded to metallization layers that are provided on the upper semiconductor layers (i.e., the semiconductor layers farthest removed from the growth substrate) prior to removal of the growth substrate. With gallium nitride-based LEDs, n-type gallium nitride-based layers are typically first grown on the growth substrate and the uppermost (i.e., last grown) gallium nitride-based layer(s) are p-type gallium nitride-based layer(s). Thus, when gallium nitride-based LEDs are mounted in flip-chip orientation with the growth substrate removed, the semiconductor layer that is farthest away from the carrier substrate is typically an n-type gallium nitride-based layer, and the light may be primarily extracted through this n-type gallium nitride-based layer. Flip-chip mounting of LEDs (with the growth substrate left on or removed) may, in some cases, provide improved light extraction, heat dissipation and/or other benefits.

In flip-chip mounted LED designs that include a carrier substrate, a bond metal stack is typically used to bond the carrier substrate to the LED metallization layers that are formed on the top semiconductor layers. The metallization layers may include, for example, ohmic contact layers that may be formed directly on exposed portions of the n-type and p-type semiconductor layers, reflector (i.e., mirror) layers, barrier layers and metal contact layers. The bond metal stack may be deposited on the above-described metallization layers, and then the carrier substrate may be placed on the bond metal stack. Heat and pressure may then be applied in order to melt at least some of the metal in the bond metal stack in order to bond the bond metals to both the metallization layers and to the carrier substrate. The carrier substrate is typically bonded to the LED during a wafer-level operation (i.e., before an LED wafer has been singulated into a plurality of LED chips). The carrier substrate may comprise, for example, a silicon or sapphire wafer, and may have one or more metal layers formed on the surface thereof that contacts the bond metal stack. The bond metal stack may comprise, for example, a multilayer stack of metals including gold-tin, nickel-tin or other metals having low melting points along with other metals such as nickel, gold, titanium and/or platinum. In some cases, the carrier substrate is left on the finished device, while in other cases the carrier substrate may be used to provide support to the device during patterning and/or thinning operations that are performed on the growth substrate, and thereafter the carrier substrate may be removed.

### SUMMARY

Pursuant to embodiments of the present invention, light emitting devices are provided that include a light emitting diode that comprises a semiconductor layer stack having a plurality of semiconductor layers that are stacked in a first direction, the semiconductor layers including an n-type semiconductor layer and a p-type semiconductor layer that is on top of the n-type semiconductor layer. These light emitting devices further include a p-contact metallization stack that has at least one metal layer that is on top of and electrically connected to the p-type semiconductor layer. An opening extends through the p-type semiconductor layer and the p-contact metallization stack. This opening has a first region that penetrates the p-type semiconductor layer to expose the n-type semiconductor layer and a second region that is above the first region that penetrates the p-contact metallization stack. The light emitting devices also include a bond metal stack that has at least one bond metal that is on top of the p-contact metallization stack. Finally, the light emitting devices include a metal spacer layer that is between the bond metal stack and the semiconductor layer stack, the metal spacer layer filling the first region of the opening and at least partly filling the second region of the opening so that a lower surface of the bond metal stack is above a top surface of the p-type semiconductor layer. The metal spacer layer may comprise one or more metals that have a higher melting point than at least one of the metals included in the bond metal stack.

In some embodiments, the metal spacer layer may fill the second region of the opening so that the lower surface of the bond metal stack is above a top surface of the p-contact metallization stack. These light emitting devices may also include a dielectric layer on the p-contact metallization stack, and the opening may include a third region that is above the second region that penetrates the dielectric layer, the metal spacer layer to fill the third region of the opening so that a lower surface of the bond metal stack is above a top surface of the dielectric layer.

In some embodiments, the metal spacer layer may comprise a metal that does not react with metals included in the bond metal stack at temperatures below about 300 degrees Celsius. The light emitting devices may also include a carrier wafer on the bond metal stack opposite the p-contact metallization stack. At least one of the bond metals may include tin, and the bond metal stack may include voids. At least one of these voids may be above the opening.

In some embodiments, the metal spacer layer may be an aluminum layer. The depth of the opening in the first direction may be between about 1 micron and about 3 microns. The metal spacer layer may have a thickness in the first direction that is at least about 1.5 times a depth of the opening in the first direction. The p-contact metallization stack may include an ohmic contact layer that is directly on the p-type semiconductor layer, a reflector layer on the ohmic contact layer, and a barrier layer on the reflector layer. The light emitting devices may also include an n-type ohmic contact layer that is directly on the n-type semiconductor layer and on a sidewall of the opening so as to partially fill the opening, where the metal spacer layer is between the n-type ohmic contact layer and the bond metal stack.

Pursuant to further embodiments of the present invention, light emitting devices are provided that include a light emitting diode that has a semiconductor layer stack that includes a plurality of semiconductor layers that are stacked in a first direction. A metallization stack that includes at least one metal layer is directly on top of a first semiconductor layer that is an uppermost of the semiconductor layers in the semiconductor layer stack. An insulating layer is on top of the metallization stack, and an opening extends through the insulating layer, the metallization stack and part way through the semiconductor layer stack to expose a top surface of a second semiconductor layer in the semiconductor layer stack, the opening having a first depth in the first direction. A bond metal stack that includes at least one bond metal is on the metallization stack. A metal spacer layer is in the opening between the bond metal stack and the semiconductor layer stack, the metal spacer layer having a first thickness in the first direction that is at least half the first depth.

In some embodiments, the light emitting device further includes an ohmic contact layer that is directly on the second semiconductor layer, where the metal spacer layer is between the ohmic contact layer and the bond metal stack. The first thickness may be greater than the first depth in some embodiments. The metal spacer layer may consist essentially of one or more metals that have a higher melting point than at least one of the metals included in the bond metal stack. The metal spacer layer may comprise, for example, an aluminum layer. The depth of the opening in the first direction may be between about 1 micron and about 3 microns in some embodiments, and the metal spacer layer may have a thickness in the first direction that is at least about 1.5 times a depth of the opening in the first direction. The metal spacer layer may be a conformal layer that includes a plurality of recesses, and the bond metal stack may fills in the recesses in the metal spacer layer.

Pursuant to still further embodiments of the present invention, light emitting devices are provided that include a light emitting diode that has a semiconductor layer stack that with an uppermost semiconductor layer. A plurality of non-semiconductor layers are on top of the uppermost semiconductor layer. A plurality of openings penetrate through at least some of the non-semiconductor layers. A conformal metal spacer layer is provided on top of the non-semiconductor layers, the metal spacer layer filling the openings. A bond metal layer stack that includes at least one bond metal is on the metal spacer layer. A mounting substrate is on the bond metal layer stack.

### BRIEF DESCRIPTION OF THE DRAWINGS

FIG. 1 is a schematic cross-sectional view of a conventional LED-based light emitting device part of the way through the manufacture thereof.

FIG. 2 is a schematic cross-sectional view of the conventional light emitting device of FIG. 1 after it has been bonded to a carrier substrate.

FIG. 3 is an enlarged view of one of the contact openings in the light emitting device of FIG. 2 that illustrates how voids may form in a bonding metal stack that is used to bond an LED of the light emitting device to the carrier substrate.

FIG. 4 is an enlarged view of one of the contact openings in another conventional light emitting device.

FIG. 5 is a plan view of a light emitting device according to embodiments of the present invention.

FIG. 6 is a cross-sectional view of the light emitting device of FIG. 5 taken along line 6-6 of FIG. 5.

FIG. 7 is an enlarged view of one of the contact openings illustrated in FIG. 6.

FIG. 8 is a plan view of a light emitting device according to further embodiments of the present invention.

FIG. 9 is a cross-sectional view of the light emitting device of FIG. 8 taken along line 9-9 of FIG. 8.

FIG. 10 is an enlarged view of one of the contact openings in the light emitting device of FIG. 9.

FIG. 11 is a cross-sectional view illustrating a metal spacer layer design according to further embodiments of the present invention.

FIG. 12 is a cross-sectional view illustrating a metal spacer layer design according to still further embodiments of the present invention.

FIG. 13 is a cross-sectional view of a light emitting device according to further embodiments of the present invention.

FIG. 14 is a cross-sectional view of a light emitting device according to still further embodiments of the present invention.

### DETAILED DESCRIPTION

Pursuant to embodiments of the present invention, light emitting devices are provided that include an LED with metallization layers thereon that has an uneven mounting surface that is bonded to a mounting structure using a bond metal stack. In these light emitting devices, a metal spacer layer is provided between the LED and the bond metal stack. The metal spacer layer may be used to increase the distance between the bond metal stack and the LED. The metal spacer layer may be relatively thick (e.g., at least as thick as the uneven mounting surface topology in some embodiments). It has been discovered that an uneven mounting surface topology may lead to the formation of voids in the bond metal stack, particularly in the vicinity of recesses in the mounting surface. These voids may compromise the structural integrity of the light emitting device during, for example, subsequent processing operations such as singulating the LED wafer into a plurality of LED chips. By way of example, thin semiconductor layers or thin dielectric layers may be more prone to cracking during the singulating operations. If voids are present in layers that are close to these thin semiconductor or dielectric layers, the stresses applied to the wafer during singulating operations may cause the thin semiconductor and/or dielectric layers to crack. The metal spacer layer may increase the distance between the thin semiconductor and dielectric layers in the LED and any voids in the bond metal stack, thereby reducing or eliminating the extent to which these voids may compromise the structural integrity of fragile layers within the device structure. In some embodiments, the LED may be a gallium nitride-based LED and the metal spacer layer may comprise an aluminum layer.

In some embodiments, the LED may be flip-chip mounted onto a carrier substrate or other mounting structure via the bond metal stack. The uneven mounting surface topology may result from contact holes that penetrate metallization and/or dielectric layers that are formed on the semiconductor layers in order to make electrical contact to at least one of the semiconductor layers. The metal spacer layer may partially or completely fill the contact holes so that the bond metal stack is only present in upper portions of the contact holes or is not within the contact holes at all. In some cases, thick metal spacer layers may be used that may have thicknesses of 1.5 times, 2 times or more the depth of the contact holes. The use of such metal spacer layers may space any voids in the bond metal stack sufficiently far away from the semiconductor and dielectric layers so that the voids may have little or no impact on these layers. The metal(s) in the metal spacer layer may have melting points that are higher than the melting points of at least some of the metals in the bond metal stack. The melting point(s) of the metal(s) in the metal spacer layer may also be higher than the temperature that the device is subjected to as part of the bonding operation that is performed to bond the carrier substrate to the device so that the metal spacer layer does not melt during the bonding operation. The metal(s) in the metal spacer layer may also be metals that do not react with the metals in the bond metal stack at the temperatures at which the bond metal stack is subjected to during the bonding operation.

Embodiments of the present invention will now be described with reference to the attached figures.

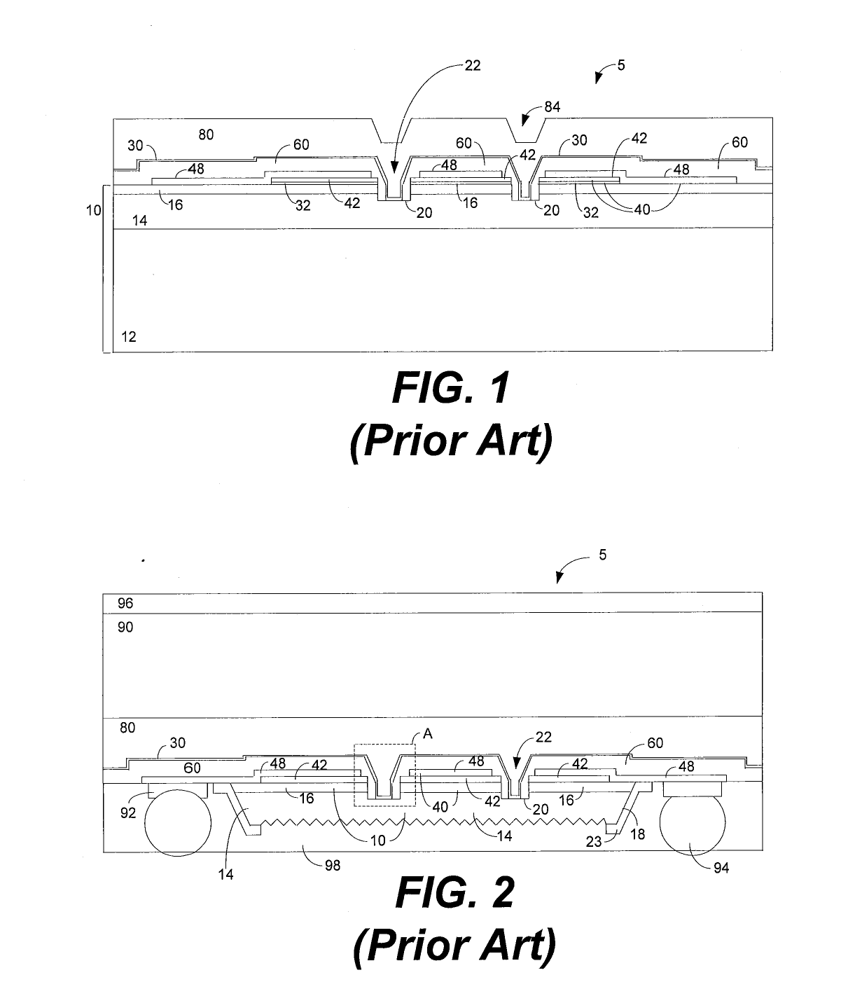

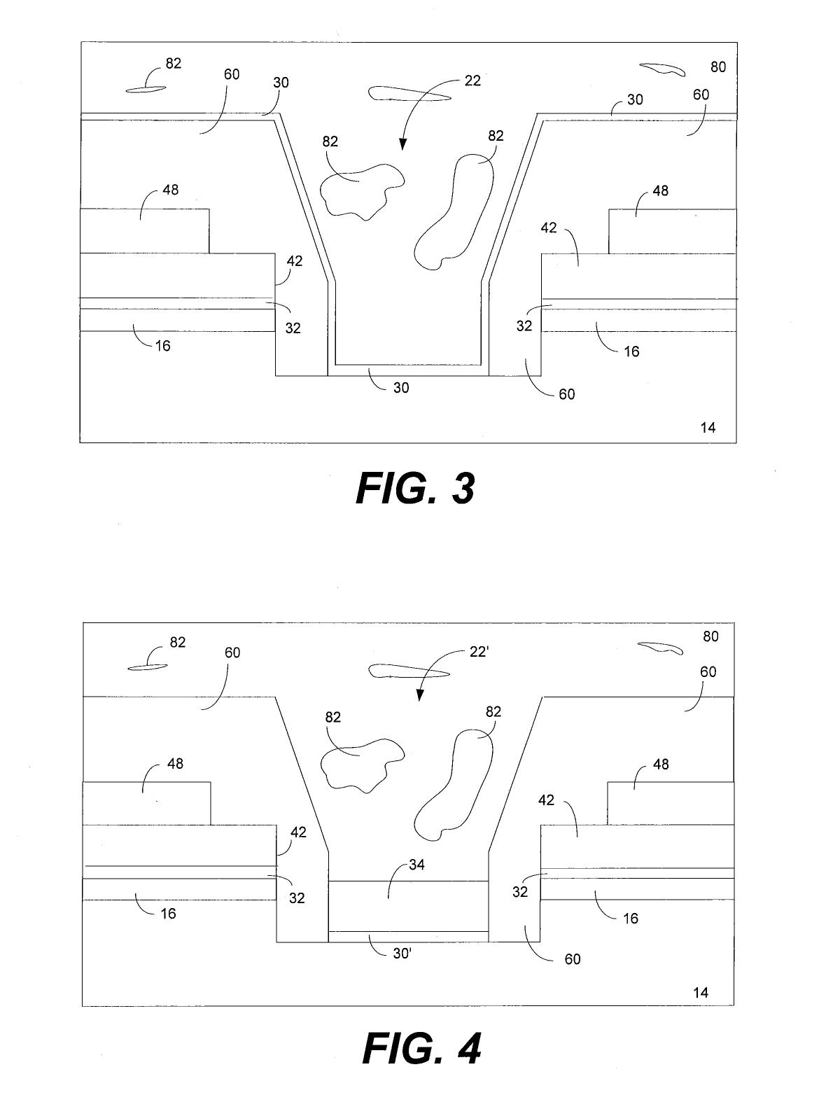

FIGS. 1-3 illustrate a conventional LED-based light emitting device 5. In particular, FIG. 1 is a schematic cross-sectional view of the light emitting device 5 part of the way through the manufacture thereof. FIG. 2 is a schematic cross-sectional view of the light emitting device 5 after fabrication has been completed. FIG. 3 is an enlarged view of one of the n-type contact openings shown in FIG. 2 that illustrates how voids may form in a bonding metal stack that is used to bond an LED of the light emitting device 5 to a carrier substrate thereof.

As shown in FIG. 1, the light emitting device 5 includes an LED 10. The LED 10 includes a growth substrate 12 and a plurality of semiconductor layers that are grown on the growth substrate 12. The semiconductor layers include at least one n-type semiconductor layer 14 and at least one p-type semiconductor layer 16. While not shown in FIG. 1, the semiconductor layers 14, 16 may include a variety of structures such as super-lattices, quantum wells and the like that provide, for example, increased light emission. As shown in FIG. 1, the uppermost of the semiconductor layers 14, 16 may be a p-type semiconductor layer 16 and the n-type semiconductor layers 14 may be below the uppermost p-type semiconductor layer 16.

A reflector 42 may be formed on an upper surface of the p-type semiconductor layer 16. The reflector 42 may comprise a single layer or may be a multi-layer structure. The reflector 42 may redirect light that is generated in the semiconductor layers 14, 16 that travels through the p-type semiconductor layer 16 back into the LED 10. The reflector 42 may increase the luminous flux generated by the light emitting device 5.

A barrier layer 48 is provided on the reflector 42. The barrier layer 48 may comprise, for example, a multi-layer stack of layers that may reduce or prevent metal atoms in the reflector 42 from migrating into other regions of the device 5. The barrier layer 48 may surround both an upper surface and one or more side surfaces of the reflector 42. The barrier layer 48 may comprise, for example, a stacked series of titanium-tungsten layers and platinum layers.

Openings 20 may be formed through the barrier layer 48, the reflector 42 and the p-type semiconductor layer 16 to expose one or more of the n-type semiconductor layers 14. A dielectric layer 60 is formed on the reflector 42, the barrier layer 48 and on the exposed n-type semiconductor layer 14. The dielectric layer 60 may be formed conformally over the substrate 12 and may form on sidewalls of the openings 20 to form contact holes 22 that have smaller diameter than the openings 20. The dielectric layer 60 may comprise, for example, a silicon nitride layer. The dielectric layer 60 may insulate exposed sidewalls of the p-type semiconductor layer 16 and the n-type semiconductor layers 14 in the contact holes 22. The dielectric layer 60 may also insulate the reflector 42 and barrier layer 48 from a bond metal stack 80.

An n-type ohmic contact layer 30 is deposited on the n-type semiconductor layer 14 in the contact holes 22 and on the dielectric layer 60. The n-type ohmic contact layer 30 may be conformally formed across the substrate 12 and hence may form on the sidewalls and bottom surface of the contact holes 22. The n-type ohmic contact layer 30 may be deposited directly on the n-type semiconductor layer 14 that is exposed by the contact holes 22. The n-type ohmic contact layer 30 may comprise, for example, a multi-layer stack of metals that make an ohmic contact to the exposed n-type semiconductor layer 14 and which adhere well to both the exposed n-type semiconductor layer 14 and to a metal layer that is deposited on top of the n-type ohmic contact layer 30 during a subsequent fabrication process. For example, if the uppermost n-type semiconductor layer 14 is an n-type gallium nitride based semiconductor layer, the n-type ohmic contact layer 30 may comprise a multi-layer aluminum/titanium/nickel/gold/titanium metal stack, with the aluminum layer being the bottommost layer in the stack (i.e., the aluminum layer may directly contact the uppermost n-type semiconductor layer 14).

A p-type ohmic contact layer 32 may be formed on an upper surface of the p-type semiconductor layer 16. The p-type ohmic contact layer 32 may comprise a metal layer that forms an ohmic contact with the p-type semiconductor layer 16. The p-type ohmic contact layer 32 may be a thin layer that is deposited directly on the p-type semiconductor layer 16. The p-type ohmic contact may or may not be provided between the reflector 42 and the p-type semiconductor layer 16. The p-type ohmic contact layer 32, the reflector 42 and the barrier layer 48 may together form at least a portion of a p-contact metallization stack 40 that is formed on the LED 10.

A bond metal stack 80 is deposited on the n-type ohmic contact layer 30. As shown in FIG. 1, the bond metal stack 80 may fill the contact holes 22. The bond metal stack 80 may comprise, for example, a multi-layer metal stack that includes, for example, nickel and nickel-tin or gold and gold-tin. In an example embodiments, the bond metal stack 80 may comprise a titanium/platinum/nickel/gold-tin/gold/gold-tin/gold metal stack.

Referring now to FIG. 2, the device of FIG. 1 may be bonded to a carrier substrate 90. In particular, the bond metal stack 80 may be used to bond the LED 10 with layers 30, 40, 60 thereon to the carrier substrate 90. The carrier substrate 90 is placed on the bond metal stack 80. The carrier substrate 90 may be any suitable substrate such as, for example, a silicon substrate or other low cost substrate. The device 5 may then be heated to a temperature that is sufficient to melt at least some of the metals in the bond metal stack 80 (e.g., the layers that include tin) and pressure may be applied to both the growth substrate 12 (see FIG. 1) and the carrier substrate 90 (see FIG. 2). As a result, the carrier substrate 90 may be bonded to the LED 10 with layers 30, 40, 60 thereon.

Still referring to FIG. 2, next, the growth substrate 12 may be removed to expose the bottommost of the n-type semiconductor layers 14. One or more of the n-type semiconductor layers may also be partially or completely removed. The remaining semiconductor layers 14, 16 may then be etched so that the semiconductor layers 14, 16 comprise a mesa structure 18 that protrudes downwardly from the remainder the device 5. As shown in FIG. 2, the exposed bottommost n-type semiconductor layer 14 may then be patterned to provide improved light extraction. Insulating spacers 23 may be formed on sidewalls of the mesa structure 18. Bond pads 92 and bump bonds 94 may be formed on lateral extensions of the barrier layer 48 to provide external contacts to the p-type semiconductor layer 16 through the p-contact metallization stack 40. A phosphor layer 98 may optionally be deposited on mesa structure 18 and the bump bonds 94. The phosphor layer 98 may include luminescent materials that, for example, down-convert at least some of the light emitted by the LED 10 to light having other wavelengths. A die attach metal 96 may be formed on the top surface of the carrier substrate 90. The die attach metal 96 may be used to mount the light emitting device to a another structure such as, for example, a submount (not shown).

It should be noted that the light emission occurs through the exposed bottom surface of the bottommost n-type semiconductor layer 14, and hence the light will be emitted from the bottom of the light emitting device when it is in the orientation shown in FIG. 2. Throughout this specification, the light emitting devices will generally be described when the devices are oriented as shown in FIGS. 1 and 2, where the growth substrate 12 forms the “bottom” of the device and the p-type semiconductor layer 16 is the “top” semiconductor layer. However, it will be appreciated that the LED 10 is typically flipped over after it is mounted to the carrier substrate 90, and the remaining operations performed to fabricate the device 5 will typically be done with the device rotated 180 degrees from the orientation shown in FIG. 2.

FIG. 3 is an enlarged view of the portion of FIG. 2 that is within the box labeled “A.” FIG. 3 illustrates how voids 82 may form in the bond metal stack 80, particularly in portions of the bond metal stack 80 that are within or near the contact openings 22.

As shown in FIG. 3, it has been discovered that voids 82 may form in the bond metal stack 80. These voids 82 may form for at least two reasons. First, the bond metal stack 80 may be a conformal layer (or a partially conformal layer), and hence, as deposited, the top surface of the bond metal stack 80 may have recesses 84 above the contact holes 22 (see FIG. 1). This may result in less bond metal material in the vicinity of the contact holes 22 when the pressure is applied to the carrier substrate 90 and the growth substrate 12 during the bonding operation. Second, a reaction occurs as the tin (or other metal) in the bond metal stack 80 melts during the high temperature operation that is performed to bond the carrier substrate 90 to the LED 10. For example, when a bond metal stack 80 containing tin and nickel along with other metal layers is used, as the tin in the bond metal stack 80 melts during the high temperature operation it reacts with the adjacent layers to form a solid solution. As the tin forms this solid solution the overall volume of the bond metal stack 80 decreases, which may result in voids 82. Thus, as shown in FIG. 3, voids 82 may form in the bond metal stack 80, particularly in the vicinity of the contact holes 22.

The semiconductor layers 14, 16 may be thin layers that may be prone to cracking if subjected to undue stress. Likewise, the dielectric layer 60 may also be a thin layer that may be prone to cracking. If the metallization layers 30, 40, 80 are free of voids, then these layers (and the carrier substrate 90) may structurally support the semiconductor layers 14, 16 and the dielectric layer 60 during subsequent processing operations. Accordingly, when the wafer is singulated into individual light emitting devices, the stresses applied to the semiconductor layers 14, 16 and the dielectric layer 60 during the dicing operation may not result in damage to these layers. However, when the voids 82 are present and located in relatively close proximity to the semiconductor layers 14, 16 and/or the dielectric layer 60, the structural support provided to these layers by the thicker bond metal stack 80 and carrier substrate 90 may be compromised, and the thin semiconductor layers 14, 16 and/or dielectric layer 60 may crack or otherwise be damaged. Such cracks may degrade device performance or lead to possible short-circuits that can result in device failure.

As shown in FIG. 3, in conventional devices the bond metal stack 80 may fill much of the contact holes 22, and the voids 82 may form in portions of the bond metal stack 80 that are within or near the contact holes 22. As a result, the voids 82 may be in close proximity to the thin semiconductor layers 14, 16 and/or the dielectric layer 60. During the dicing operation, these voids can contribute to the formation of cracks in the thin semiconductor layers 14, 16 and/or in the thin dielectric layer 60.

FIG. 4 is an enlarged view of an n-type contact opening 22′ in another conventional light emitting device. The device of FIG. 4 is very similar to the light emitting device of FIGS. 1-3, except that in the device of FIG. 4, the n-type ohmic contact layer 30 is replaced with an n-type ohmic contact layer 30′ that is only formed in the bottom of the contact holes 22′ (as opposed to being conformally formed on the dielectric layer 60), and an additional via-fill layer 34 is formed on the n-type ohmic contact layer 30′. The via-fill layer 34 fills the portion of the contact opening 22′ that is in the semiconductor layers 14, 16, The via-fill layer 34 may comprise a nickel/tin layer, or a nickel/tin layer that includes additional elements such as titanium, platinum, palladium, aluminum and/or other metals depending on the properties desired of the metal layers. The via-fill layer 34 may, in effect, comprise part of the bond metal stack 80, and may itself be subject to void formation. As shown in FIG. 4, voids 82 may still form within the contact opening 22′ as the bond metal stack 80 fills much of the contact opening 22′.

Pursuant to embodiments of the present invention, LED-based light emitting devices are provided that have an uneven mounting surface that is bonded to a mounting structure (e.g., a carrier wafer) using a bond metal stack. In these light emitting devices, a metal spacer layer may be provided between the LED and the bond metal stack in order to increase the distance between the bond metal stack and thin, fragile layers in the device such as certain semiconductor and/or dielectric layers. The metal spacer layer may increase the distance between these fragile layers and any voids that may form in the bond metal stack during a bonding operation. As such, improved performance and/or reliability may be achieved.

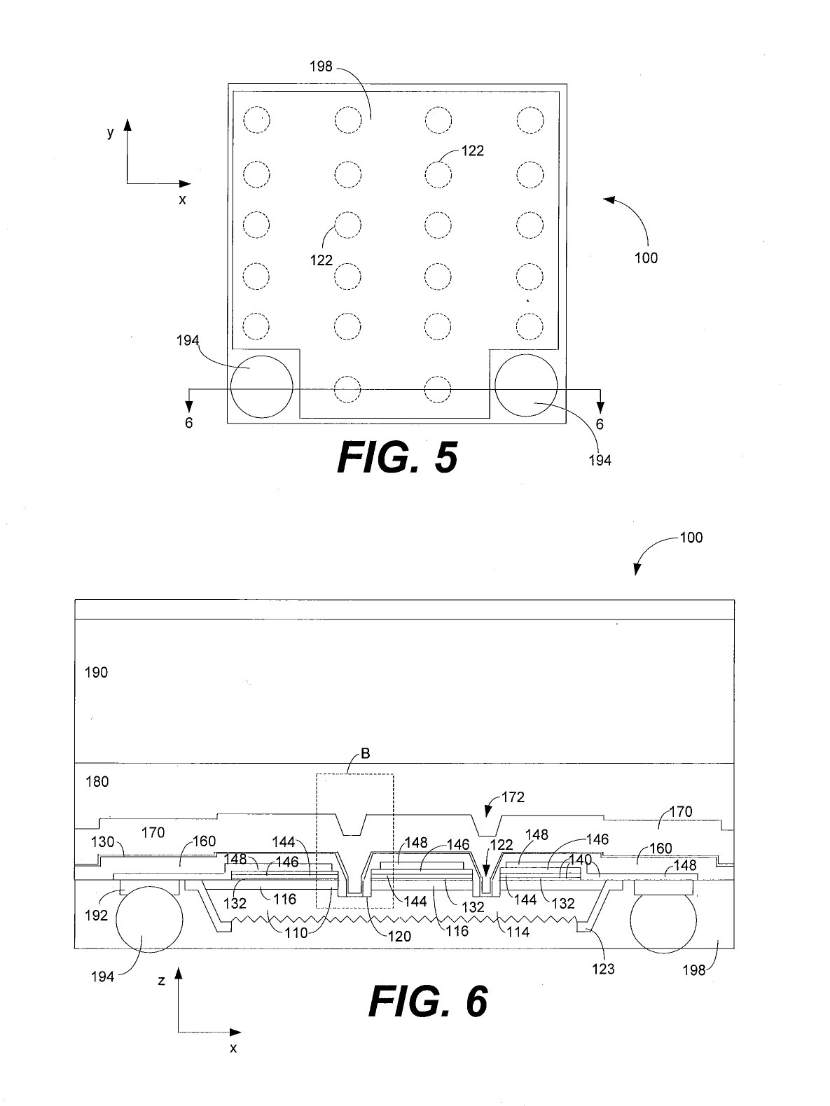

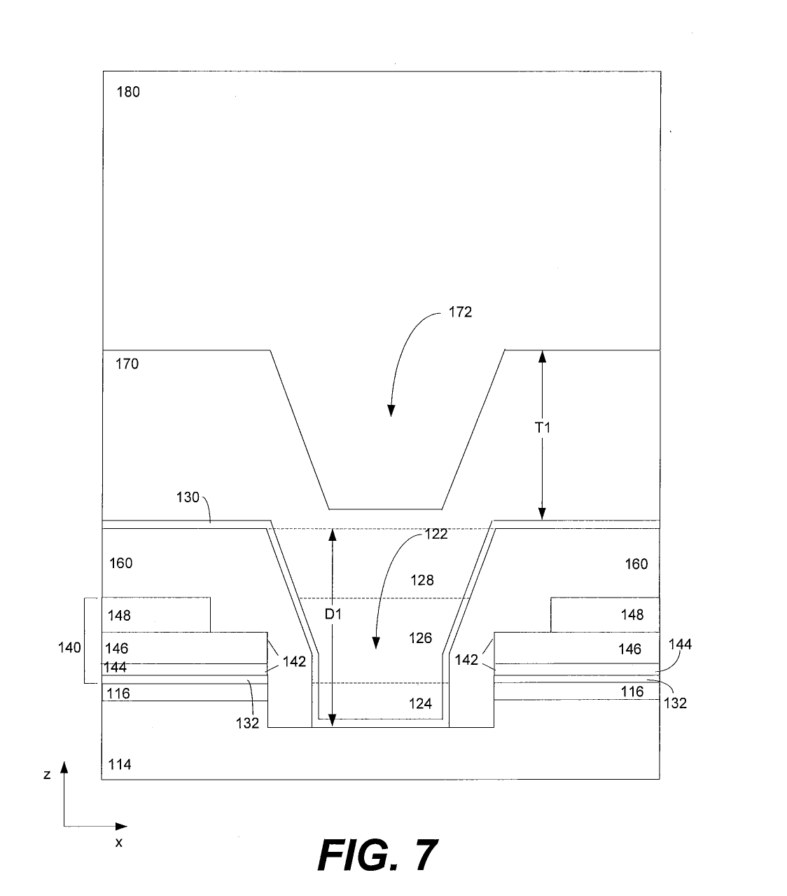

FIG. 5 is a plan view of a light emitting device 100 according to embodiments of the present invention. FIG. 6 is a cross-sectional view of the light emitting device 100 taken along the line 6-6 of FIG. 5. FIG. 7 is an enlarged view of a region labeled “B” in FIG. 6 that illustrates how the metal spacer layer may increase the distance between various fragile layers in the device 100 and portions of the bond metal stack where voids are likely to form.

As shown in FIGS. 5-6, the light emitting device 100 includes an LED 110 that has been mounted on a carrier substrate 190. The LED includes n-type semiconductor layers 114 and at least one p-type semiconductor layer 116. The semiconductor layers 114, 116 may be stacked in the z-direction. The LED 110 may be grown on a growth substrate (not shown) that is removed after the LED 110 is mounted on the carrier substrate 190. While not shown in FIG. 6, the semiconductor layers 114, 116 may include a variety of semiconductor structures such as super-lattices, quantum wells and the like that provide, for example, for increased light emission. The uppermost of the semiconductor layers may be a p-type semiconductor layer 116 and the n-type semiconductor layers 114 may be below the uppermost p-type semiconductor layer 116. The n-type and p-type semiconductor layers 114, 116 may primarily comprise gallium nitride based layers such as, for example, some combination of gallium nitride, aluminum gallium nitride, indium gallium nitride and indium aluminum gallium nitride layers. Other non-gallium nitride based layers may be included such as, for example, an aluminum nitride buffer layer.

A p-type ohmic contact layer 132 is formed on an upper surface of the p-type semiconductor layer 116. In some embodiments, the p-type ohmic contact layer 132 may comprise a thin nickel layer. In other embodiments, the p-type ohmic contact layer 132 may comprise a transparent indium-tin-oxide (“ITO”) layer. For purposes of this disclosure, transparent metal oxide layers such as ITO are considered to be metal layers. Both materials may make ohmic contacts to p-type gallium nitride based layers. Other materials may additionally or alternatively be used. The p-type ohmic contact layer 132 may be conformally deposited on the exposed upper surface of the p-type semiconductor layer 116 or may be selectively deposited (e.g., the p-type ohmic contact layer 132 may not be deposited in regions of the device where a reflector 142 is formed during later processing steps).

As shown in FIG. 6, the reflector 142 is formed on the upper surface of the p-type semiconductor layer 116. The reflector 142 may be formed directly on the p-type semiconductor layer 116 or the p-type ohmic contact layer 132 may be interposed between the reflector 142 and the p-type semiconductor layer 116. In some embodiments, the reflector 142 may comprise a multi-layer structure that includes a reflector oxide layer 144 and a reflector metal layer 146. The reflector oxide layer 144 may comprise, for example, a silicon oxide layer. The reflector metal layer 146 may comprise, for example, a silver layer or an aluminum layer. The reflector 142 may redirect light that is generated by the LED 110 that travels through the p-type semiconductor layer 116 back into the LED 110 so that at least a portion thereof may be emitted through the n-type semiconductor layers 114. The reflector 142 may increase the luminous, flux generated by the light emitting device 100.

A barrier layer 148 is provided on the reflector 142. The barrier layer 148 may comprise, for example, a multi-layer stack of metal layers that may reduce or prevent metal atoms in the reflector metal layer 146 from migrating into other regions of the light emitting device 100. In some embodiments, the barrier layer 148 may surround both an upper surface and one or more side surfaces of the reflector 142. In other embodiments, the barrier layer 148 may only be on an upper surface of the reflector 142. The barrier layer 148 may comprise, for example, a series of alternately stacked titanium-tungsten layers and nickel layers or a series of alternately stacked titanium-tungsten and platinum layers. The p-type ohmic contact layer 132, the reflector 142 and the barrier layer 148 may together form at least a portion of a p-contact metallization stack 140.

Openings 120 extend through the barrier layer 148, the reflector 142, the p-type ohmic contact layer 132 and the p-type semiconductor layer 116 to expose the n-type semiconductor layers 114. A dielectric layer 160 is formed on the reflector 142, the barrier layer 148 and on the exposed n-type semiconductor layer 114. The dielectric layer 160 may be on sidewalls of the openings 120 to form contact holes 122 that have smaller diameters than the openings 120. The dielectric layer 160 may comprise, for example, a silicon nitride layer. The dielectric layer 160 may insulate exposed sidewalls of the p-type semiconductor layer 116 and the n-type semiconductor layers 114 in the contact holes 122. One potential arrangement of the contact holes 122 is shown in FIG. 5. It will be appreciated that the number of contact holes 122 and the positions thereof may be varied from what is shown in FIG. 5. The contact holes 122 are shown using dotted lines in FIG. 5 as they do not extend to the top surface of the device 100.

An n-type ohmic contact layer 130 is deposited on the n-type semiconductor layer 114 in the contact holes 122. The n-type ohmic contact layer 130 may be formed on the sidewalls and bottom surface of the contact holes 122. The n-type ohmic contact layer 130 may be deposited directly on the n-type semiconductor layer 114 that is exposed by the contact holes 122. The n-type ohmic contact layer 130 may also be formed on the upper surface of the dielectric layer 160. The n-type ohmic contact layer 130 may comprise, for example, a multi-layer stack of metals that make an ohmic contact to the uppermost n-type semiconductor layer 114 and which adhere well to both the uppermost n-type semiconductor layer 114 and to a metal layer that is deposited on top of the n-type ohmic contact layer 130 during a subsequent fabrication process. For example, if the uppermost n-type semiconductor layer 114 is a gallium nitride based semiconductor layer, the n-type ohmic contact layer 130 may comprise an aluminum/titanium/nickel/gold/titanium metal stack, with the aluminum layer being the bottommost layer in the stack (i.e., the aluminum layer may directly contact the uppermost n-type semiconductor layer 114).

A metal spacer layer 170 is formed on the dielectric layer 160. The metal spacer layer 170 may comprise a relatively thick layer that does not melt during the operation that is performed to bond the carrier substrate 190 to the remainder of the light emitting device 100. Stated differently, the metal spacer layer 170 may comprise one or more metals that have a higher melting point than at least one of the metals included in the bond metal stack. For example, the bond metal stack 180 may include tin, which melts at about 240° C. The carrier substrate 190 bonding operation may be carried out, for example, at a temperature of about 260-280° C. The metal spacer layer 170 may be formed of a metal or metals having melting points well above 280° C. The metal spacer layer 170 may also comprise a material that does not substantially react with the bond metal stack 180 during the carrier substrate 190 bonding operation. In some embodiments, the metal spacer layer 170 may include aluminum. In some embodiments, the metal spacer layer 170 may consist essentially of an aluminum layer. The aluminum may be deposited via, for example, sputtering or evaporation. The metal spacer layer 170 may be formed conformally on the n-type ohmic contact layer 130. Accordingly, the upper surface of the metal spacer layer 170 may have recesses 172 above the contact holes 122.

In some embodiments, the metal spacer layer 170 may have a thickness T1 that is greater than or equal to half the depth D1 of the contact hole 122. The depth D1 of the contact hole 122 is the distance in the z-direction from the top surface of the n-type semiconductor layer 114 that is exposed at the bottom of the contact hole 122 to the top surface of the dielectric layer 160 (see FIG. 7). In some embodiments, the metal spacer layer 170 may have a thickness T1 that is greater than or equal to the depth D1 of the contact hole 122. In such embodiments, the metal spacer layer 170 may completely fill the remainder of the contact hole 122 (i.e., the portion not filled by the n-type ohmic contact layer 130). Thus, a bond metal stack 180 that is used to bond the carrier substrate 190 to the remainder of the device 100 will be outside the contact holes 122 in such embodiments. In some embodiments, the metal spacer layer 170 may have a thickness T1 that is at least twice the depth D1 of the contact hole 122. In these embodiments, the bond metal stack may be a significant distance from the fragile semiconductor and dielectric layers 114, 116, 160.

The bond metal stack 180 is deposited on the metal spacer layer 170. While not shown in FIGS. 6 and 7, the bond metal stack 180 may be deposited conformally and hence there may be recesses in an upper surface of the bond metal stack 180 above the contact holes 122. The bond metal stack 180 may comprise, for example, a multi-layer metal stack that includes nickel and nickel-tin or gold and gold-tin. In example embodiments, the bond metal stack 180 may comprise a titanium/platinum/nickel/gold-tin/gold/gold-tin/gold metal stack.

The bond metal stack 180 is used to bond the carrier substrate 190 to the LED 110 with the various metallization layers and the dielectric layer 160 thereon. The carrier substrate 190 may be any suitable substrate such as, for example, a silicon substrate or other low cost substrate. The carrier substrate 190 may be placed on the bond metal stack 180 and the device 100 may then be heated to a temperature that is sufficient to melt at least some of the metals in the bond metal stack 180 (e.g., the layers that include tin) and pressure may be applied to both a growth substrate (not shown in the figures) and the carrier substrate 190. As a result, the carrier substrate 190 may be bonded to the device 100 and the metallization and other layers 130, 140, 160, 180. The growth substrate may then be removed and the device may be processed in the same fashion as the light emitting device 5 that is discussed above to arrive at the finished light emitting device 100 pictured in FIGS. 5-7. As noted above, the bond metal stack 180 may be conformally formed on the device. However, as shown in FIGS. 6 and 7, during the operation in which the carrier substrate 190 is bonded to the device metal in the bond metal stack is melted and pressure is applied to both sides of the device and the upper surface of the bond metal stack 180 may become planarized during this operation as shown in FIG. 6.

As is also shown in FIG. 6, the exposed bottommost n-type semiconductor layer 114 may be patterned to provide improved light extraction. The LED 110 may also be patterned to have a mesa structure and insulating spacers 123 may be formed on sidewalls of the mesa structure. Bond pads 192 and bump bonds 194 may be formed on lateral extensions of the barrier layer 148 to provide external contacts to the p-type semiconductor layers 116 through the p-contact metallization stacks 140.

FIG. 7 is an enlarged view of a region labeled “B” in FIG. 6 that illustrates how the metal spacer layer 170 may increase the distance between various fragile layers in the light emitting device 100 and portions of the bond metal stack 180 where voids 182 are likely to form.

As shown in FIG. 7, the contact hole 122 may be considered to have three separate regions. A first region 124 of the contact hole 122 is the portion of the contact hole 122 that penetrates the semiconductor layers 114, 116. The n-type ohmic contact layer 130 may at least partly fill this first region 124. In embodiments of the present invention, any portion of the first region 124 that is not filled by the n-type ohmic contact layer 130 may be filled by the metal spacer layer 170.

The contact hole 122 may also include a second region 126 that is directly above the first region 124 and in fluid communication therewith (i.e., before the contact hole 122 is filled, a fluid could pass from the second region 126 to the first region 124). The second region 126 may be the portion of the contact hole 122 that penetrates the p-contact metallization stack 140. As noted above, this p-contact metallization stack 140 may include one or more of, for example, a p-type ohmic contact layer 132, a reflector 142 and a barrier layer 148. In some embodiments of the present invention, the metal spacer layer 170 may partly or completely fill the second region 126 of the contact hole 122.

The contact hole 122 may also include a third region 128 that is directly above the second region 126 and in fluid communication therewith. The third region 128 may be the portion of the contact hole 122 that penetrates the portion of the dielectric layer 160 that is on the p-contact metallization stack 140. In some embodiments of the present invention, the metal spacer layer 170 may also partly or completely fill the third region 128 of the contact hole 122.

In some embodiments, the contact openings 122 may have a depth D1 of between about 1 micron and about 3 microns. The metal spacer layer 170 may have a thickness T1 that is at least half the depth D1. In some embodiments, the thickness T1 of the metal spacer layer 170 may be at least equal to the depth D1 so that the metal spacer layer 170 may fill the contact holes 122. In some embodiments, the thickness T1 of the metal spacer layer may be 1.5 times, 2 times, 3 times or even more the depth D1 of the contact hole 122.

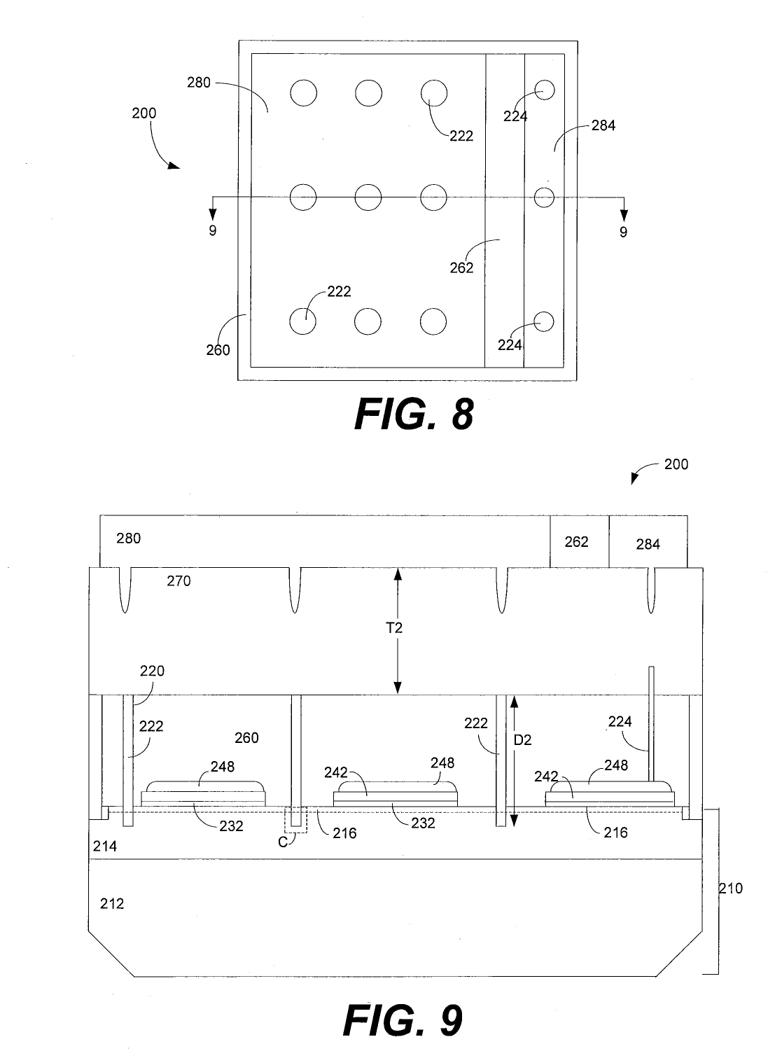

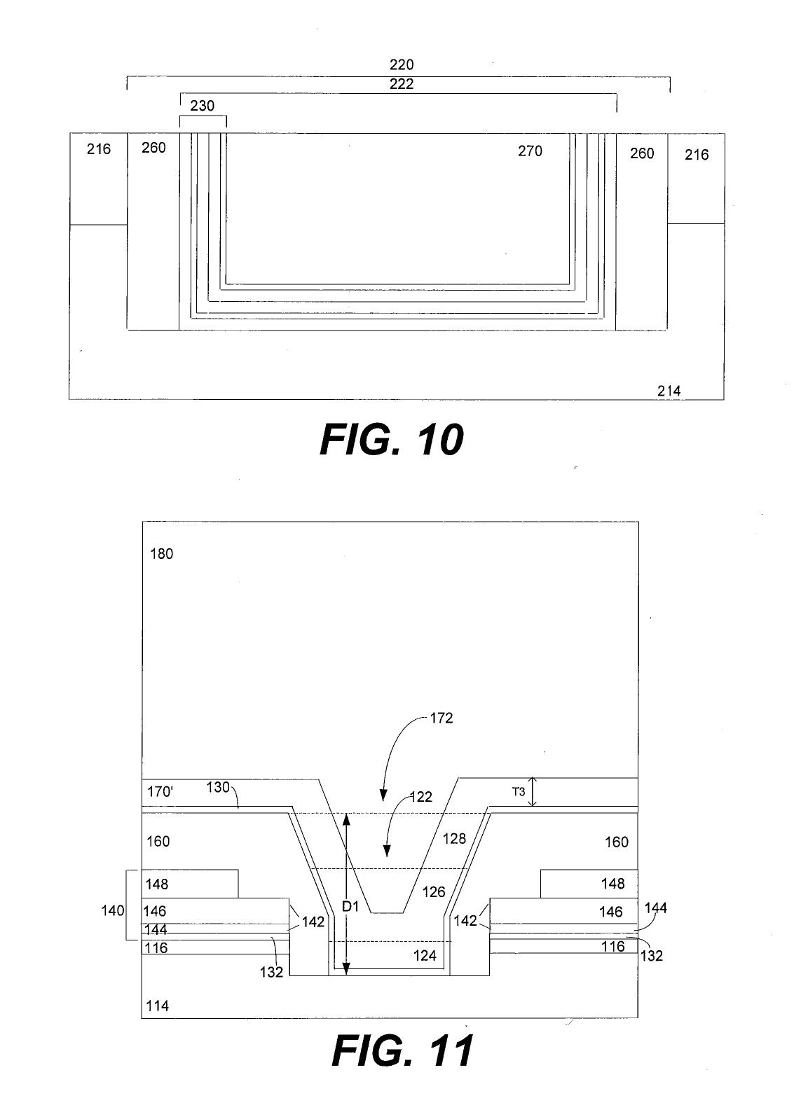

FIG. 8 is a plan view of a light emitting device 200 according to further embodiments of the present invention. FIG. 9 is a cross-sectional view of the light emitting device 200 of FIG. 8. FIG. 10 is an enlarged view of the region labeled “C” in FIG. 9.

Referring to FIGS. 8-10, the light emitting device 200 includes an LED 210. The LED 210 includes n-type semiconductor layers 214 and at least one p-type semiconductor layer 216 that are grown on a growth substrate 212. In the depicted embodiment the growth substrate 212 may be, for example, a silicon carbide or a sapphire growth substrate, although other growth substrates may be used. The growth substrate 212 may be thinned to reduce the thickness of the device 200 and/or may be patterned to improve light extraction. The semiconductor layers 214, 216 may include a variety of semiconductor structures such as super-lattices, quantum wells and the like (not shown). The “uppermost” of the semiconductor layers 214, 216 may be the p-type semiconductor layer 216 and the n-type semiconductor layers 214 may be below the uppermost p-type semiconductor layer 216. The n-type and p-type semiconductor layers 214, 216 may comprise gallium nitride based semiconductor layers. Light is emitted from the LED 210 through the growth substrate 212.

A p-type ohmic contact layer 232 is formed on an upper surface of the p-type semiconductor layer 216. The p-type ohmic contact layer 232 may comprise a thin nickel layer. A reflector 242 is formed on the upper surface of the p-type ohmic contact layer 232. The reflector 242 may comprise a multi-layer structure that includes, for example, a silver layer and a titanium layer. The reflector 242 may redirect light that is generated by the LED 210 that travels through the p-type semiconductor layer 216 back into the LED 210 for emission through the growth substrate 212.

A barrier layer 248 is provided on the reflector 242. The barrier layer 248 may comprise, for example, a multi-layer stack of metal layers that may reduce or prevent metal atoms in the reflector 242 from migrating into other regions of the device 200. The barrier layer 248 may comprise, for example, a series of alternately stacked titanium-tungsten layers and nickel layers or a series of alternately stacked titanium-tungsten and platinum layers. The p-type ohmic contact layer 232, the reflector 242 and the barrier layer 248 may each be part of a p-contact metallization stack 240 that is formed on the LED 210. One or more of the p-type ohmic contact layer 232, the reflector 242 and the barrier layer 248 may be omitted in some embodiments from the p-contact metallization stack 240.

Openings 220 extend through the barrier layer 248, the reflector 242, the p-type ohmic contact layer 232 and the p-type semiconductor layer 216 to expose an n-type semiconductor layer 214. A dielectric layer 260 is formed on the reflector 242, the barrier layer 248 and on the exposed n-type semiconductor layer 214. The dielectric layer 260 may comprise, for example, a silicon nitride layer.

The openings 220 are only schematically illustrated in FIG. 9. FIG. 10 is an enlarged view of the region labeled “C” of FIG. 9 that illustrates the layers that are formed in each of the openings 220. As shown in FIG. 10, the dielectric layer 260 is formed on the sidewall of each opening 220. The dielectric layer 260 may insulate exposed sidewalls of the p-type semiconductor layer 216 and the n-type semiconductor layers 214. The dielectric layer 260 decreases the size of each opening 220 (e.g., the radius of the opening 220 for circular openings) to define contact holes 222.

As is also shown in FIG. 10, an n-type ohmic contact layer 230 is deposited on the n-type semiconductor layer 214 in the contact holes 222. The n-type ohmic contact layer 230 may be formed on the sidewalls and bottom surfaces of the contact holes 222. The n-type ohmic contact layer 230 may be deposited directly on the exposed n-type semiconductor layer 214. The n-type ohmic contact layer 230 may comprise, for example, a multi-layer stack of such as, for example, an aluminum/titanium/nickel/gold/titanium metal stack, with the aluminum layer being the bottommost layer in the stack (i.e., the aluminum layer may directly contact the uppermost n-type semiconductor layer 214).

Referring to FIGS. 9 and 10, a metal spacer layer 270 is formed on the dielectric layer 260 and within the contact holes 222. In some embodiments, the metal spacer layer 270 may have a thickness T2 that is greater than or equal to half the depth D2 of the contact hole 222. In some embodiments, the metal spacer layer 270 may fill the contact holes 222. In some embodiments, the thickness T2 of the metal spacer layer 270 may be greater than or equal to the depth D2 of the contact hole 222. In such embodiments, a bond metal stack 280, 284 that is used to bond the light emitting device 200 to a mounting structure (not shown) will not be within the contact holes 222 (as the metal spacer layer 270 will fill the remainder of the contact openings 222), and hence will be spaced a significant distance from the semiconductor layers 214, 216. The metal spacer layer 270 may be formed of a metal that does not melt during the operation (described below) that is performed to bond the light emitting device 200 to the mounting structure. The metal spacer layer 270 may comprise one or more metals that have a higher melting point than at least one of the metals included in the bond metal stack 280, 284. The metal spacer layer 270 may comprise a material that does not substantially react with the bond metal stack 280, 284 during the bonding operation. In some embodiments, the metal spacer layer 270 may include aluminum. In some embodiments, the metal spacer layer 270 may consist essentially of an aluminum layer. The aluminum may be deposited via, for example, sputtering or evaporation. As shown in FIG. 9, the metal spacer layer 270 may be formed conformally on the underlying dielectric layer 260.

The bond metal stack 280, 284 is formed on the metal spacer layer 270. The bond metal stack may initially be formed as a single layer (not shown) and then may be patterned into an n-type contact bond metal stack 280 and a p-type contact bond metal stack 284, as shown in FIGS. 8-9. A dielectric layer 262 such as, for example, a silicon nitride layer may be formed between the n-type contact bond metal stack 280 and the p-type contact bond metal stack 284 to electrically insulate the two bond metal stacks 280, 284 from each other. Each bond metal stack 280, 284 may comprise, for example, a multi-layer metal stack that includes, for example, nickel and nickel-tin or gold and gold-tin. In example embodiments, the bond metal stacks 280, 284 may comprise a titanium/platinum/nickel/gold-tin/gold/gold-tin/gold metal stack. The bond metal stacks 280, 284 are used to mount the light emitting device 200 to a mounting substrate (not shown) such as a submount. The bond metal stacks 280, 284 may also be used to mount the light emitting device 200 to a carrier substrate during an intermediate fabrication step.

FIG. 11 is a cross-sectional view corresponding to the region “B” of FIG. 6 that illustrates a metal spacer layer 170′ according to further embodiments of the present invention. As shown in FIG. 11, the metal spacer layer 170′ is similar to the metal spacer layer 170 of the light emitting device 100 of FIGS. 5-7, except that the metal spacer layer 170′ has a thickness T3 that is less than the thickness T1 of metal spacer layer 170. As a result, the metal spacer layer 170′ does not fill the remainder of the contact hole 122, but instead only fills the first region 124 that is between the exposed n-type semiconductor layer 114 and a plane defined by the upper surface of the p-type semiconductor layer 116, and partially fills the second region 126 that is between the first region and a plane defined by the upper surface of the barrier layer 148. Other than the change to the metal spacer layer 170, the device of FIG. 11 may be identical to the light emitting device 100 of FIGS. 5-7.

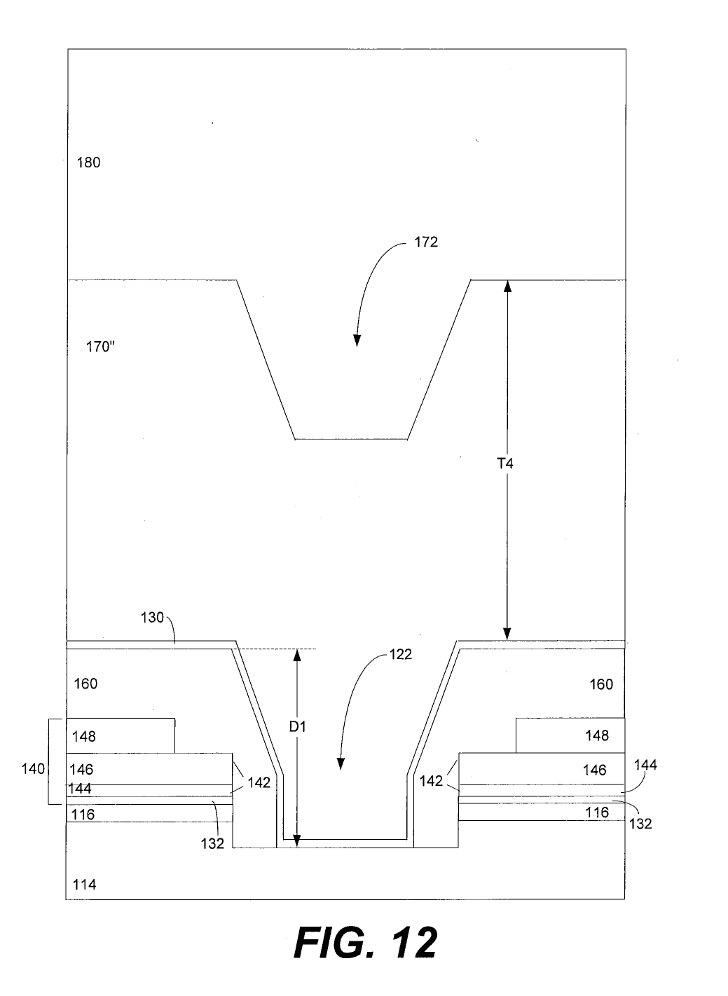

FIG. 12 is a cross-sectional view corresponding to the region “B” of FIG. 6 that illustrates a metal spacer layer 170″ according to still further embodiments of the present invention. As shown in FIG. 12, the metal spacer layer 170″ is similar to the metal spacer layer 170 of the light emitting device 100 of FIGS. 5-7, except that the metal spacer layer 170″ has a thickness T4 that is at least twice the thickness T1 of metal spacer layer 170. As a result, the thickness T4 of the metal spacer layer 170″ is at least twice the depth D1 of the contact hole, thereby further spacing the bond metal stack 180 away from the semiconductor layers 114, 166. Other than the change to the metal spacer layer 170, the device of FIG. 12 may be identical to the light emitting device 100 of FIGS. 5-7.

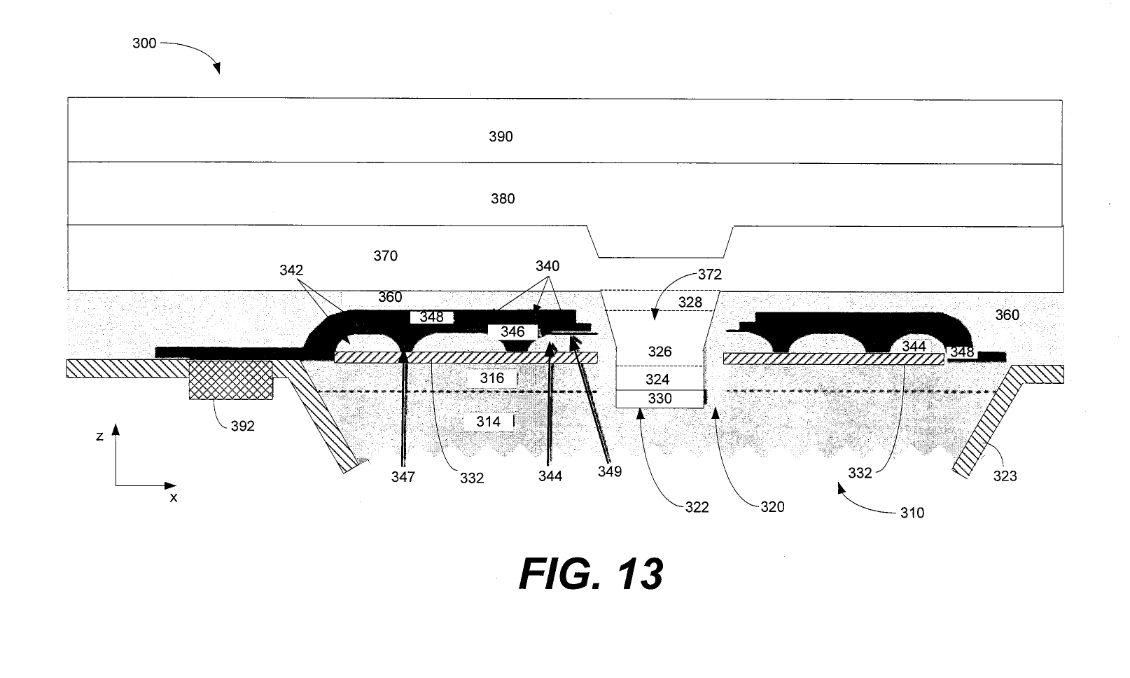

FIG. 13 is a cross-sectional view of a light emitting device 300 according to further embodiments of the present invention. The light emitting device 300 is similar to the light emitting device 100 of FIG. 5-7 but includes a different p-contact metallization stack structure, as is explained below.

As shown in FIG. 13, the light emitting device 300 includes an LED 310 that is mounted on a carrier substrate 390. The LED 310 includes n-type semiconductor layers 314 and at least one p-type semiconductor layer 316 that are stacked in the z-direction. The LED 310 may be grown on a growth substrate (not shown) that is removed after the LED 310 is mounted on the carrier substrate 390. The semiconductor layers 314, 316 may be identical to the n-type and p-type semiconductor layers 114, 116 included in the LED 110 that is discussed above, and hence further description thereof will be omitted.

A transparent ITO p-type ohmic contact layer 332 is formed on an upper surface of the p-type semiconductor layer 316. A multi-layer reflector 342 is formed on the upper surface of the p-type ohmic contact layer 332. The reflector 342 includes a reflector oxide layer 344 and a reflector metal layer 346. The reflector oxide layer 344 may comprise, for example, a silicon oxide layer. The reflector metal layer 346 may comprise, for example, a silver layer. The reflector metal layer 346 may have downwardly extending protrusions 347 that penetrate the reflector oxide layer 344 to make electrical contact to the p-type ohmic contact layer 332. A barrier layer 348 is provided on the reflector 342. The barrier layer 348 may be identical to the barrier layer 148 that is discussed above, and hence further description thereof will be omitted. A titanium-oxynitride layer 349 is provided as an adhesion layer between the reflector oxide layer 344 and the reflector metal layer 346. The p-type ohmic contact layer 332, the reflector 342 and the barrier layer 348 may together form at least a portion of a p-contact metallization stack 340.

An opening 320 extends through the barrier layer 348, the reflector 342, the p-type ohmic contact layer 332 and the p-type semiconductor layer 316 to expose an n-type semiconductor layer 314. A dielectric layer 360 (e.g., silicon nitride) is formed on the reflector 342, the barrier layer 348 and on the exposed n-type semiconductor layer 314. The dielectric layer 360 extends onto the sidewalls of the opening 320 to form a contact hole 322 that has a smaller diameter than the opening 320. A blanket street mirror (not shown) may be formed on an upper surface of the dielectric layer 360. The blanket street mirror may comprise, for example, aluminum.

An n-type ohmic contact layer 330 may be deposited directly on the n-type semiconductor layer 314 in the contact hole 322. The n-type ohmic contact layer 330 may be formed on the sidewalls and bottom surface of the contact hole 322. The n-type ohmic contact layer 330 may be identical to the n-type ohmic contact layer 130 that is discussed above, and hence further description thereof will be omitted.

A metal spacer layer 370 is formed on the dielectric layer 360. The metal spacer layer 370 may be identical to the metal spacer layer 130 that is discussed above. Accordingly, the metal spacer layer 370 may comprise a relatively thick layer that includes one or more metals such as aluminum that do not melt during the operation that is performed to bond the carrier substrate 390 to the remainder of the device 300 and that do not substantially react with the bond metal stack 380 during the carrier substrate 390 bonding operation. The upper surface of the metal spacer layer 370 may have a recess 372 above the contact hole 322.

The metal spacer layer 370 may have a thickness that is greater than or equal to half the depth of the contact hole 322. In some embodiments, the metal spacer layer 370 may have a thickness that is greater than the depth of the contact hole 322.

The bond metal stack 380 is deposited on the metal spacer layer 370. The bond metal stack 380 may be identical to the bond metal stack 180 discussed above, and hence further description thereof will be omitted. The bond metal stack 380 is used to bond the carrier substrate 390 to the remainder of the device 300. The carrier substrate 390 may be identical to the carrier substrate 190 that is discussed above, and hence further description thereof will be omitted.

The exposed bottommost n-type semiconductor layer 314 may be patterned to provide improved light extraction. The LED 310 may also be patterned to have a mesa structure, and insulating spacers 323 may be formed on sidewalls of the mesa structure. A bond pad 392 may be formed on a lateral extension of the barrier layer 348 to provide an external contact to the p-type semiconductor layer 316 through the p-contact metallization stack 340.

As shown in FIG. 13, the contact hole 322 may have three separate regions. A first region 324 is the portion of the contact hole 322 that penetrates the semiconductor layers 314, 316. The n-type ohmic contact layer 330 may at least partly fill this first region 324. A second region 326 that is directly above the first region 324 may be the portion of the contact hole 322 that penetrates the p-contact metallization stack 340. In some embodiments, the metal spacer layer 370 may completely fill any portion of the first region 324 that is not filled by the n-type ohmic contact layer 330 and may partly or completely fill the second region 326. The contact hole 322 may also include a third region 328 that is directly above the second region 326. In some embodiments, the metal spacer layer 370 may also partly or completely fill the third region 328.

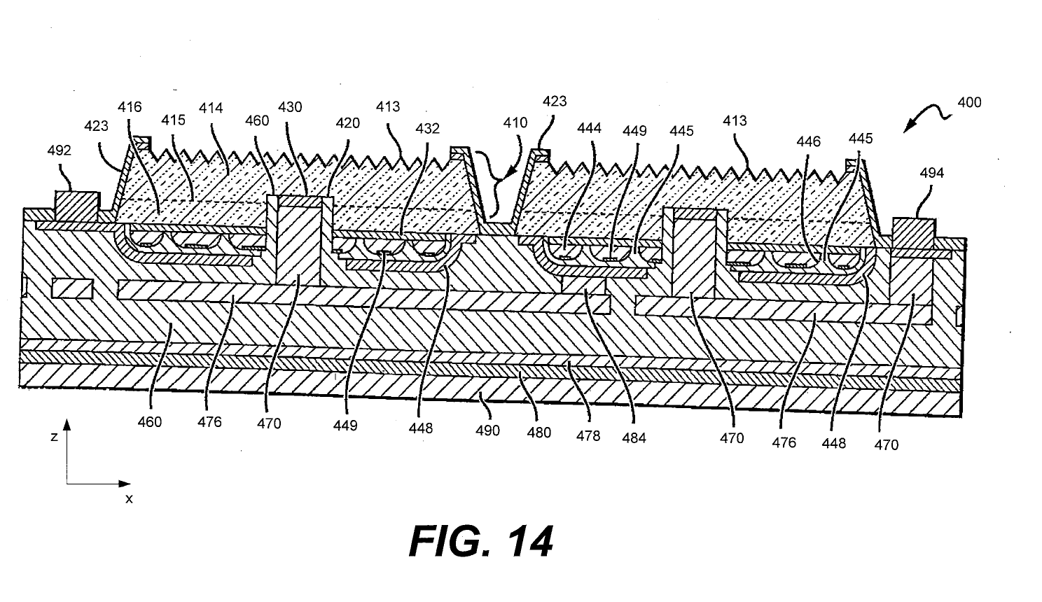

FIG. 14 is a cross-sectional view of a light emitting device 400 according to still further embodiments of the present invention. The light emitting device 400 includes a pair of LEDs 410 that are mounted on a carrier substrate 490. The LEDs are electrically interconnected as will be explained below to provide a monolithic device 400 including multiple LEDs 410. While two LEDs are shown in FIG. 14, it will be appreciated that more than two LEDs may be provided and interconnected in the light emitting device 400.

Each LED 410 includes n-type semiconductor layers 414 and at least one p-type semiconductor layer 416 that are stacked in the z-direction. The LEDs 410 may be grown on a growth substrate (not shown) that is removed after the LEDs 410 are mounted on the carrier substrate 490. The semiconductor layers 414, 416 may be identical to the n-type and p-type semiconductor layers 114, 116 included in the LED 110 that is discussed above, and hence further description thereof will be omitted. A dotted line labeled 415 in FIG. 14 schematically illustrates the junction between the n-type and p-type layers 414, 416. An exposed surface of the topmost n-type semiconductor layer may have a patterned surface 413 to improve light extraction. Each LED 410 may be patterned to have a mesa structure and insulating spacers 423 may be formed on sidewalls of each mesa structure.

A transparent ITO p-type ohmic contact layer 432 is formed on an upper surface of the p-type semiconductor layer 416. A multi-layer reflector that includes a reflector oxide layer 444 and a reflector metal layer 446 is provided on the p-type ohmic contact layer 432. The reflector oxide layer 444 may comprise, for example, a silicon oxide layer. The reflector metal layer 446 may comprise, for example, a silver layer. The reflector metal layer 446 may have downwardly extending protrusions 445 that penetrate the reflector oxide layer 444 to make electrical contact to the p-type ohmic contact layer 432. A barrier layer 448 is provided on the reflector metal layer 446. The barrier layer 448 may be identical to the barrier layer 148 that is discussed above, and hence further description thereof will be omitted. A titanium-oxynitride layer 449 is provided as an adhesion layer between the reflector oxide layer 444 and the reflector metal layer 446.

An opening 420 extends through the barrier layer 448, the reflector 444/446, the p-type ohmic contact layer 432 and the p-type semiconductor layer 416 to expose an n-type semiconductor layer 414. A dielectric layer 460 (e.g., silicon nitride) is formed on the reflector 444/446, the barrier layer 448 and on the exposed n-type semiconductor layer 414. The dielectric layer 460 extends onto the sidewalls of the opening 420 to form a contact hole 422 that has a smaller diameter than the opening 420.

An n-type ohmic contact layer 430 may be deposited directly on the n-type semiconductor layer 414 in the contact hole 422. The n-type ohmic contact layer 430 may be formed on the sidewalls and bottom surface of the contact hole 422. The n-type ohmic contact layer 430 may be identical to the n-type ohmic contact layer 130 that is discussed above, and hence further description thereof will be omitted.

A metal spacer pattern 470 is formed on the dielectric layer 460. The metal spacer pattern 470 may fill the remainder of the contact holes 422. The metal spacer pattern 470 may comprise a relatively thick layer that includes one or more metals such as aluminum that do not melt during the operation that is performed to bond the carrier substrate 490 to the remainder of the device 400 and that do not substantially react with the bond metal stack 480 during the carrier substrate 490 bonding operation.

The metal spacer pattern 470 may have a thickness that is greater than or equal to half the depth of the contact hole 422. As shown in FIG. 14, in some embodiments, the metal spacer pattern 470 may have a thickness that is greater than the depth of the contact hole 422. A p-contact plug 484 may be provided on the barrier layer 448. In some embodiments, the p-contact plug 484 may be formed simultaneously with the metal spacer pattern 470 and may comprise the same material as the metal spacer pattern 470.

A p-type bond pad 492 may be formed on lateral extension of the barrier layer 448 of the left LED 410 in FIG. 14, and an n-type type bond pad 494 may be formed that is electrically connected to the n-type ohmic contact layer 430 of the right LED 410 in FIG. 14. The bond pads 492, 494 provide external contacts to power the LEDs 410.

The LEDs 410 may be electrically connected in, for example, series, by electrically connecting the n-type ohmic contact layer 430 of the left LED 410 in FIG. 14 to the p-type ohmic contact layer 432 of the right LED 410 in FIG. 14, and connecting the n-type ohmic contact layer 430 of the right LED to an n-type bond pad 494. As shown in FIG. 14, interconnection metal layers 476 are provided in the dielectric layer 460 to provide these electrical connections.

A blanket street mirror 478 may be formed on the dielectric layer 460. The blanket street mirror 478 may comprise, for example, aluminum.

The bond metal stack 480 is deposited on the blanket street mirror 478. The bond metal stack 480 may be identical to the bond metal stack 180 discussed above, and hence further description thereof will be omitted. The bond metal stack 480 is used to bond the carrier substrate 490 to the remainder of the device 400. The carrier substrate 490 may be identical to the carrier substrate 190 that is discussed above, and hence further description thereof will be omitted.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

The present invention has been described with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. For example, the cross-sectional drawings use different horizontal (x-direction) and vertical (z-direction) scales which may differ by a factor of one hundred or more. Like numbers refer to like elements throughout. As used herein the term “and/or” includes any and all combinations of one or more of the associated listed items.

The terminology used herein is for the purpose of describing particular embodiments only and is not intended to be limiting of the invention. The singular forms “a”, “an” and “the” are intended to include the plural forms as well, unless the context clearly indicates otherwise. It will be further understood that, when used in this specification, the terms “comprises” and/or “including” and derivatives thereof, specify the presence of stated features, operations, elements, and/or components, but do not preclude the presence or addition of one or more other features, operations, elements, components, and/or groups thereof. Herein references to an element “consisting essentially of” certain materials means that the element includes the stated materials except for insubstantial amounts of other materials that do not materially affect the properties or operation of the element.

It will be understood that, although the terms first, second, etc. may be used herein to describe various elements, components, regions and/or layers, these elements, components, regions and/or layers should not be limited by these terms. These terms are only used to distinguish one element, component, region or layer from another dement, component, region or layer. Thus, a first element, component, region or layer discussed below could be termed a second element, component, region or layer without departing from the teachings of the present invention.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure.

The expression “light emitting device,” as used herein, is not limited, except that it be a device that is capable of emitting light.

In the drawings and specification, there have been disclosed embodiments of the invention and, although specific terms are employed, they are used in a generic and descriptive sense only and not for purposes of limitation, the scope of the invention being set forth in the following claims.

That which is claimed is:

1. A light emitting device, comprising:
a light emitting diode that comprises a semiconductor layer stack that includes a plurality of semiconductor layers that are stacked in a first direction, the semiconductor layers including an n-type semiconductor layer and a p-type semiconductor layer that is on top of the n-type semiconductor layer;
a p-contact metallization stack that includes at least one metal layer that is on top of and electrically connected to the p-type semiconductor layer;
an opening in the p-type semiconductor layer and the p-contact metallization stack that has a first region that penetrates the p-type semiconductor layer to expose the n-type semiconductor layer and a second region that is above the first region that penetrates the p-contact metallization stack;
a bond metal stack that includes at least one bond metal on top of the p-contact metallization stack; and
a metal spacer layer between the bond metal stack and the semiconductor layer stack, the metal spacer layer filling the first region of the opening and at least partly filling the second region of the opening so that a lower surface of the bond metal stack is above a top surface of the p-type semiconductor layer, the metal spacer layer comprising one or more metals that have a higher melting point than at least one of the metals included in the bond metal stack.

2. The light emitting device of claim 1, wherein the metal spacer layer also fills the second region of the opening so that the lower surface of the bond metal stack is above a top surface of the p-contact metallization stack.

3. The light emitting device of claim 2, further comprising a dielectric layer on the p-contact metallization stack, wherein the opening including a third region that is above the second region that penetrates the dielectric layer, and wherein the metal spacer layer also fills the third region of the opening so that a lower surface of the bond metal stack is above a top surface of the dielectric layer.

4. The light emitting device of claim 1, wherein the metal spacer layer comprises a metal that does not react with metals included in the bond metal stack at temperatures below about 300 degrees Celsius.

5. The light emitting device of claim 1, further comprising a carrier wafer on the bond metal stack opposite the p-contact metallization stack.

6. The light emitting device of claim 1, wherein the at least one bond metal includes tin, and wherein the bond metal stack includes voids.

7. The light emitting device of claim 6, wherein at least one of the voids in the bond metal stack is above the opening.

8. The light emitting device of claim 1, wherein the metal spacer layer comprises an aluminum layer.

9. The light emitting device of claim 3, wherein a depth of the opening in the first direction is between about 1 micron and about 3 microns.

10. The light emitting device of claim 1, wherein the metal spacer layer has a thickness in the first direction that is at least about 1.5 times a depth of the opening in the first direction.

11. The light emitting device of claim 1, wherein the p-contact metallization stack includes an ohmic contact layer that is directly on the p-type semiconductor layer, a reflector layer on the ohmic contact layer, and a barrier layer on the reflector layer.

12. The light emitting device of claim 1, further comprising an n-type ohmic contact layer directly on the n-type semiconductor layer and on a sidewall of the opening so as to partially fill the opening, wherein the metal spacer layer is between the n-type ohmic contact layer and the bond metal stack.

13. A light emitting device, comprising:
a light emitting diode that comprises a semiconductor layer stack that includes a plurality of semiconductor layers that are stacked in a first direction;
a metallization stack that includes at least one metal layer that is directly on top of a first semiconductor layer that is an uppermost of the semiconductor layers in the semiconductor layer stack;
an insulating layer on top of the metallization stack;
an opening that extends through the insulating layer, the metallization stack and part way through the semiconductor layer stack to expose a top surface of a second semiconductor layer in the semiconductor layer stack, the opening having a first depth in the first direction;
a bond metal stack that includes at least one bond metal on the metallization stack; and
a metal spacer layer in the opening between the bond metal stack and the semiconductor layer stack, the metal spacer layer having a first thickness in the first direction that is at least half the first depth.

14. The light emitting device of claim 13, further comprising an ohmic contact layer directly on the second semiconductor layer, the metal spacer layer between the ohmic contact layer and the bond metal stack.

15. The light emitting device of claim 13, wherein the first thickness is greater than the first depth.

16. The light emitting device of claim 1, wherein the metal spacer layer consists essentially of one or more metals that have a higher melting point than at least one of the metals included in the bond metal stack.

17. The light emitting device of claim 16, wherein the metal spacer layer comprises an aluminum layer.

18. The light emitting device of claim 13, wherein a depth of the opening in the first direction is between about 1 micron and about 3 microns, and wherein the metal spacer layer has a thickness in the first direction that is at least about 1.5 times a depth of the opening in the first direction.

19. The light emitting device of claim 16, wherein the metal spacer layer is a conformal layer that includes a plurality of recesses, and wherein the bond metal stack fills in the recesses in the metal spacer layer.

20. A light emitting device, comprising:
a light emitting diode that comprises a semiconductor layer stack that that has an uppermost semiconductor layer;
an opening in the uppermost semiconductor layer that has a first region that penetrates the uppermost semiconductor layer to expose an underlying semiconductor layer;
a bond metal stack that includes at least one bond metal; and
a metal spacer layer between the bond metal stack and the semiconductor layer stack, the metal spacer layer filling the first region of the opening so that a lower surface of the bond metal stack is above a top surface of the uppermost semiconductor layer, the metal spacer layer comprising one or more metals that have a higher melting point than at least one of the metals included in the bond metal stack.

21. The light emitting device of claim 20, further comprising a plurality of non-semiconductor layers on top of the uppermost semiconductor layer, wherein the opening has a second region that penetrates through at least some of the non-semiconductor layers, and wherein the metal spacer layer fills the second region.

22. The light emitting device of claim 21, wherein the metal spacer layer is a conformal metal spacer layer, the light emitting device further comprising a mounting substrate on the bond metal layer stack, and wherein the metal spacer layer has a higher melting point than at least one of the metals included in the bond metal stack.
